(19) United States
(12) Patent Application Publication
(10) Pub. No.: US 2007/0001177 A1
(43) Pub. Date: Jan. 4, 2007

(54) Integrated light-emitting diode system

(75) Inventors: Gert W. Bruning, Sleepy Hollow, NY (US); James M. Gaines, Mohegan Lake, NY (US); Michael D. Pashley, Cortiandt Manor, NY (US)

Correspondence Address: PHILIPS INTELLECTUAL PROPERTY & STANDARDS, P.O. BOX 3001, BRIARCLIFF MANOR, NY, 10510, US

(73) Assignee: Koninklijke Philips Electronics N.V.

(21) Appl. No.: 10/555,679

(22) PCT Filed: Apr. 18, 2004
(86) PCT No.: PCT/IB04/01489

§ 371 Date: Nov. 4, 2005

Related U.S. Application Data
(60) Provisional application No. 60/469,058, filed on May 8, 2003.

(51) Int. Cl. H01L 33/00

(52) U.S. Cl. 257/79

(57) ABSTRACT

An integrated LED light system (100) including a printed circuit board (110, 410) and a submount (120, 420) mounted on the printed circuit board (110, 410). System (100) further includes an array of LEDs (125, 425) in electrical communication with the submount (120, 420) to receive forward currents. The array of LEDs (125, 425) includes one or more LEDs for emitting one or more color of lights in response to a reception of the forward currents from the submount (120, 420). System (100) additionally includes a heatsink (130, 430) supporting the printed circuit board (110, 410) to conduct and dissipate heat away from the printed circuit board (110, 410), the submount (120, 420), and the LED(s) (125, 425). System (100) further includes a reflector cup (140, 440) mounted on the printed circuit board (110, 410) and in optical communication with the LED(s) (125, 425) to focus the at least one color of light.

In general, the invention relates to light-emitting diode (“LED”) light sources. More specifically, the invention relates to a component integration of an LED system.

Most artificial light is produced utilizing a lamp in which an electric discharge through a gas is used to produce illumination. One such lamp is the fluorescent lamp. Another method of creating artificial light includes the use of a LED. An LED provides a light output in the form of a radiant flux that is proportional to its forward current. Additionally, an LED light source can be used for generation of a multi-spectral light output.

Presently, LED lighting systems consist of separate components, which make it difficult to implement a color control feedback. The present invention offers an integrated LED light system containing all required elements to operate properly without any need of user intervention to gather, match and test the components to assemble such a system in an application. The user does not need to concern him/herself with complex design issues, such as LED placement, sensor placement, and control system design. The user need only specify input power, a specified signal to control light color and/or intensity, and any desired second-stage optic for beam shaping.

One form of the invention includes an apparatus that is directed to an integrated LED light system including a printed circuit board and a submount mounted on the printed circuit board. The apparatus further includes an array of LEDs that is in electrical communication with the submount to receive forward currents. The array of LEDs emits one or more colors of light in response to a reception of the forward currents from the submount. The apparatus additionally includes a heatsink supporting the circuit board to conduct and dissipate heat away from the printed circuit board, the submount, and the LEDs. The apparatus further includes a reflector cup mounted on the printed circuit board and in optical communication with the LEDs to focus the color of light(s).

The foregoing form and other features and advantages of the invention will become further apparent from the following detailed description of the presently preferred embodiment, read in conjunction with the accompanying drawings. The detailed description and drawings are merely illustrative of the invention rather than limiting, the scope of the invention being defined by the appended claims and equivalents thereof.

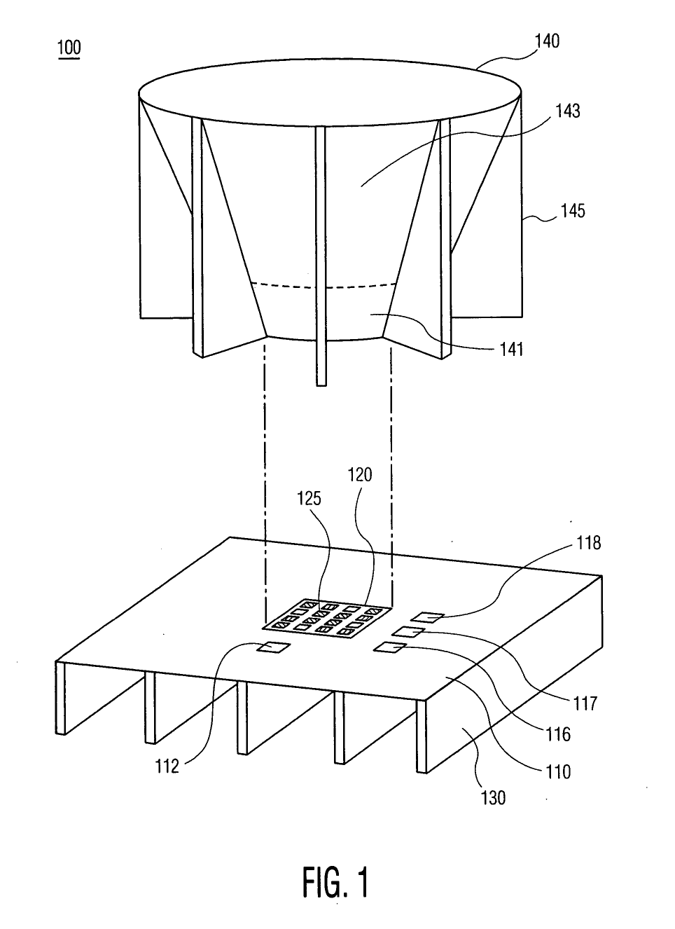

FIG. 1 illustrates a perspective view of a LED light source assembly in accordance with one embodiment of the present invention;

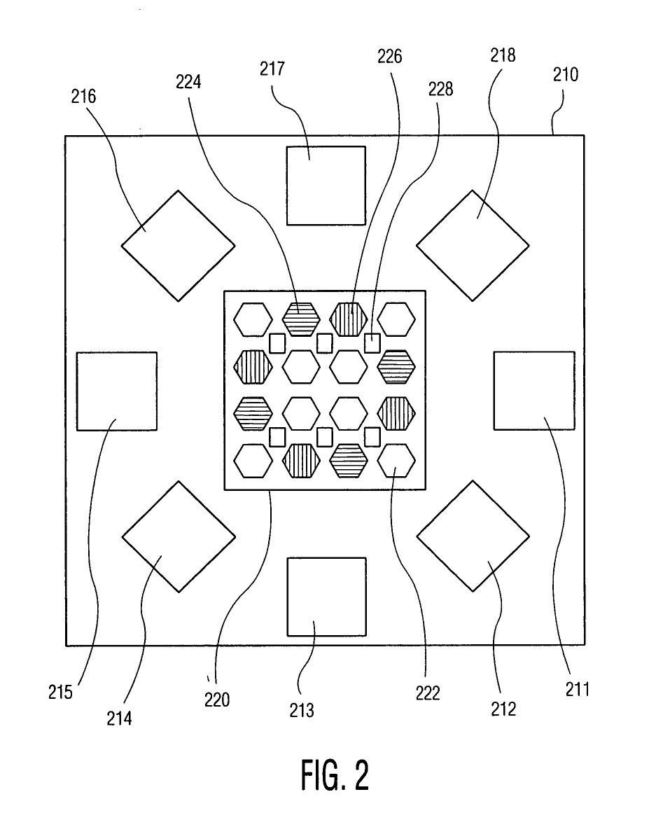

FIG. 2 illustrates a top view of a printed circuit board in accordance with one embodiment of the present invention;

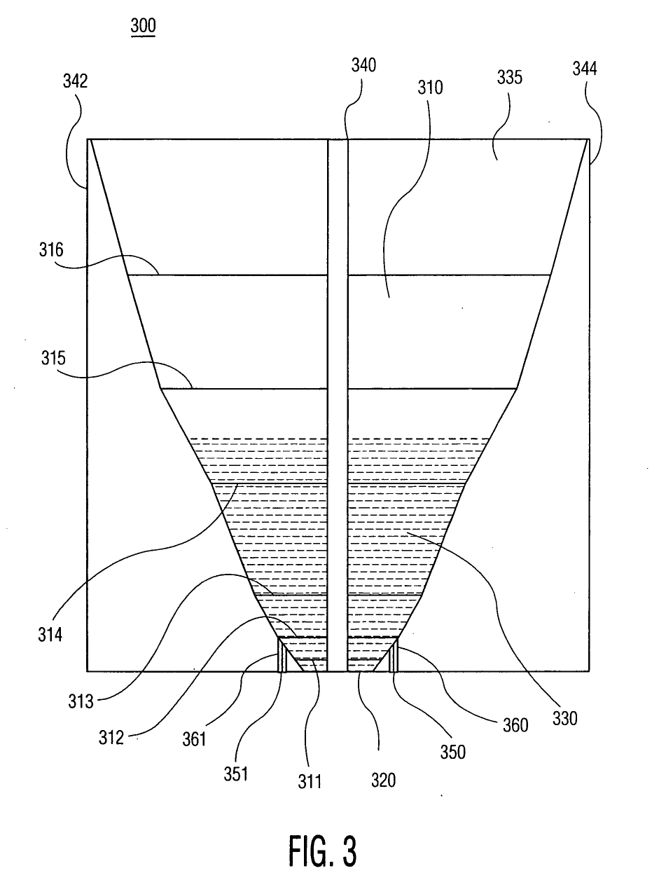

FIG. 3 illustrates a side view of a first stage optic in accordance with one embodiment of the present invention; and

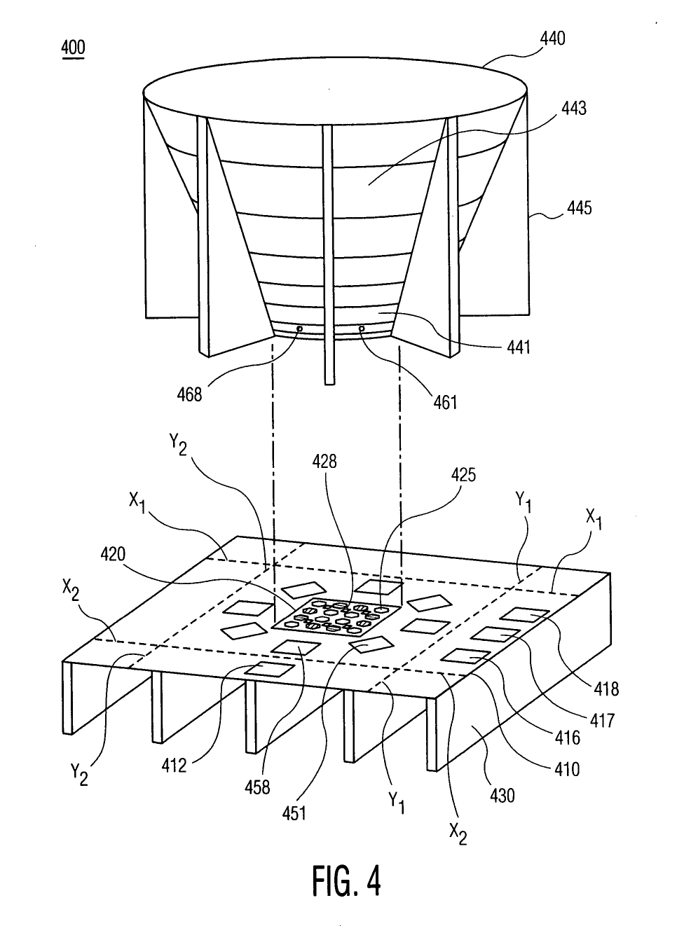

FIG. 4 illustrates a perspective view of a LED light source assembly in accordance with a second embodiment of the present invention.

FIG. 1 illustrates LED light source assembly 100 known as a light-emitting diode system-in-package (“LED-SIP”). LED light source assembly 100 primarily includes a printed circuit board (“PCB”) 110, a submount 120, a PCB heatsink 130, and a first stage optics 140. LED light source assembly 100 may include additional components not relevant to the present discussion.

PCB 110 is a mounting platform that is operatively coupled to submount 120, PCB heatsink 130, and first stage optics 140. PCB 110 includes circuitry necessary to allow submount 120 and components integrated within submount 120 to function as designed. In one embodiment, PCB 110 additionally includes interface input port 112 as well as additional mountings for discrete components 116-118 that are not integrated within submount 120, such as, for example unavoidable discrete components including inductors, capacitors and the like. Interface input port 112 provides a port for interface with submount 120 and hence assembly 100. In one embodiment, interface input port 112 provides a port for receiving operating instructions such as, for example color point instructions and on/off instructions. Interface input port 112 is designed to receive power and provide the received power to submount 120 via PCB 110 as well as providing a user interface with submount 120.

PCB 110 may additionally include sensors (not shown) operatively coupled to PCB 110, such as, in a configuration as described in FIG. 2 below. The sensors may be implemented as any suitable sensor, for example photodetectors. The sensors would provide input data for any control circuitry within LED light source assembly 100.

Additionally, PCB 110 provides a path for heat transfer from submount 120 to the ambient environment. In one embodiment, thermal build-up within submount 120 is transferred to PCB 110 due to physical contact between the two components. The thermal build-up within PCB 110 is then transferred to PCB heatsink 130 due to physical contact between the two components.

Submount 120 is a substrate including LED dice 125 operatively coupled to the substrate, such as, for example in a configuration as described in FIG. 2 below. In one embodiment, submount 120 further includes drive and control circuitry integrated within the substrate. In an example, submount 120 includes drive and control circuitry integrated within the substrate utilizing a conventional silicon-on-insulator integrated circuit process. In another embodiment, drive and control circuitry (e.g., drive MOSFETS) is located elsewhere within the assembly, such as, for example within an additional silicon chip operatively coupled to PCB 110 and in communication with submount 120. In one embodiment, submount 120 is implemented as a silicon substrate. In other embodiments, submount 120 is implemented as an electrically-insulating, thermally conducting substrate, such as, for example aluminum nitride (AIN), silicon carbide (SiC), beryllium oxide (BeO), or a naturally occurring substance, such as, diamond. The electrically-insulating, thermally conducting substrate would include metal electrical connections deposited overlying the substrate to provide direct current to the LED dice. Currently, there are many other electrically-insulating, thermally conducting substrate materials in development utilizing emerging technology, such as, for example Nano-technology that may meet the above requirements as well.

LED dice 125 are direct emitting components that are surface mounted to submount 120. LED dice 125 are direct emitting optoelectronic devices that produce light when power is supplied causing them to forward bias. The light produced may be within the blue, green, red, amber or other portion of the spectrum, depending on the material utilized in manufacturing the LED dice. In an example, LED dice 125 are implemented as the unencapsulated die portions of LXHL-PM01, LXHL-PB01 and LXHL-PD01 available from Lumileds Corporation of San Jose, Calif. In another example, LED dice 125 are implemented as the unencapsulated die portions of NSPB300A, NSPG300A and NSPR800AS from Nichia Corporation of Mountville, Pa.

PCB heatsink 130 functions to conduct and dissipate heat, as well as to provide support to PCB 110. PCB heatsink 130 is manufactured from a conductive material, such as, for example copper. In one embodiment, LEDs dice 125 are attached directly to PCB heatsink 130 through mounting holes in submount 120 and PCB 110. In this embodiment, the direct attachment allows for a more efficient thermal transfer to occur. In another embodiment, submount 120 is attached directly to PCB heatsink 130. In this embodiment, a portion of PCB 110 is removed allowing for submount 120 to be attached directly to PCB heatsink 130 allowing for a more efficient thermal transfer to occur.

First stage optics 140 is a reflector cup including an encapsulated dielectric 141 and a reflector 143. Encapsulated dielectric 141 has a refractive index greater than one (1), such as, for example silicone, plastic, or glass. In one embodiment, a combination silicone-plastic resin is utilized to form the transparent dielectric within encapsulated dielectric 141 of first stage optics 140. In another embodiment, a silicone resin is utilized to form the transparent dielectric within encapsulated dielectric 141 of first stage optics 140. In yet another embodiment, a region close to the LED dice is filled with silicone resin and the remaining area of encapsulated dielectric 141 is filled with a hard plastic. In this embodiment, both materials form the transparent dielectric within encapsulated dielectric 141. Reflector 143 functions as an externally mounted reflector. In one embodiment, reflector 143 is optional. In another embodiment, reflector 143 provides a reduction in width of a beam emitted from first stage optics 140, and hence LED light source assembly 100.

First stage optics 140 may additionally include fins 145 operatively coupled to first stage optics 140. Additionally, fins 145 are operatively coupled to PCB 110 and provide a path for heat transfer from PCB 110 to the ambient environment. In one embodiment, utilizing fins 145 allows additional transfer of thermal build-up within PCB 110 to fins 145 due to physical contact between the two components. In another embodiment, a portion of fins 145 is in physical contact with submount 120 and allows additional transfer of thermal build-up within submount 120. The result of fins 145 contacting PCB 110 or submount 120 is an increase in size of the total heatsink of LED light source assembly 100. Fins 145 may be manufactured from any suitable thermally conductive material, such as, for example copper.

In operation, LED light source assembly 100 receives power from interface input port 112. LED light source assembly 100 may receive user input from interface input port 112 as well. Power including a direct current is provided to submount 120 and to LED dice 125 surface mounted on submount 120 via PCB 110. The direct current causes LED dice 125 to forward bias and produce light. The light produced by LED dice 125 is mixed while passing through encapsulated dielectric 141 of first stage optics 140. A majority portion of the mixed light passes through reflector 143 and is emitted from LED light source assembly 100.

FIG. 2 is a top view of an embodiment of a portion of PCB 110, including submount 120, illustrated in FIG. 1. In FIG. 2, submount 220 is operatively coupled to PCB 210. In one embodiment, submount 220 is electrically as well as thermally coupled to PCB 210. Submount 220 includes a plurality of LED dice 222-226 and optional internal sensors 228. Like named and similarly numbered components function substantially similar to associated components in FIG. 1.

In one embodiment, submount 220 includes sixteen LED dice 222-226 arranged in a four-by-four (4×4) array configuration including eight (8) green (G) LED dice 222, four (4) blue (B) LED dice 224, and four (4) red (R) LED dice 226. In an example, submount 220 includes sixteen LED dice 222-226 with each die having an area of approximately one millimeter by one millimeter (1 mm×1 mm). In another example, the area of the LED dice may be less. The LED dice 222-226 are arranged in a four-by-four (4×4) array configuration having an area of five and one-half millimeters by five and one-half millimeters (5.5 mm×5.5 mm) including one-half millimeter (0.5 mm) spacing between dice. In this example, submount 220 is sized to receive LED dice 222-226 in the described configuration. In another example, submount 220 is sized to receive LED dice 222-226 in other configurations or may be additionally sized to include control circuitry as described above. In another embodiment, submount 220 additionally includes a number of amber (A) LED dice. In an example, submount 220 includes sixteen LED dice 222-226, including a number of amber (A) LED dice, arranged in a four-by-four (4×4) array configuration.

PCB 210 may additionally include a plurality of external sensors 211-218. In one embodiment, PCB 210 includes a plurality of external sensors 211-218 that are coupled to PCB 210 and in communication with control elements controlling direct current (DC) delivered to LED dice 222-226. In this embodiment, external sensors 211-218 are positioned so as not to be in a direct line of sight to LED dice 222-226. External sensors 211-218 are positioned so as to receive light reflected from an air-dielectric interface. In an example, utilization of external sensors 211-218 requires a modification of a first stage optics (detailed in FIG. 3, below) to allow refracted light to reach the external sensors. Because of the positioning, LED light travels a distance many times greater than the LED die-to-die spacing before impinging on the external sensors, and therefore is a (partial) mixture from all LED dice 222-226. External sensors 211-218 in this configuration would therefore be less sensitive to variations in the individual LED die light output. External sensors 211-218 can be implemented as any suitable light sensor, such as, for example as photodiodes including: TKP70PD available from Tyntek of Taiwan, RoC; PSS WS-7.56CH available from Pacific Silicon Sensor of Westlake Village, Calif.; and PSS 2-2CH also available from Pacific Silicon Sensor of Westlake Village, Calif.

Submount 220 may additionally include one or more internal sensors 228. In one embodiment, one or more internal sensors 228 are located within close proximity to LED dice 222-226 and are positioned so as to be in a direct line of sight to one or more LED dice 222-226. The positioning of one or more internal sensors 228 within close proximity to LED dice 222-226 allows determination of spatial light distribution based on relative intensities of light produced from the LED dice of a fixed color. Internal sensors 228 can be implemented as any suitable sensor, such as, for example TK025PD also available from Tyntek of Taiwan, RoC. In another embodiment, internal sensors are located beneath each LED die allowing for measurement of each LED die. Locating an internal sensor beneath individual dice allows monitoring of individual LED dice for degradation of the individual LED dice output. Monitoring of the degradation of the individual LED dice output results in reducing color coordinate drift.

In one embodiment, PCB 210 includes external sensors 211-218 and submount 220 includes one or more internal sensors 228. In this embodiment, a combination of the internal and external sensors allows control portions of a LED light source assembly to receive and process mixed light from the external sensors as well as determination of relative intensities of individual LED dies from internal sensors.

In another embodiment, PCB 210 does not include external sensors and submount 220 includes one or more modified internal sensors 228. In this embodiment, internal sensors 228 are modified to receive light refracted from the air-dielectric interface. The modification additionally eliminates direct reception from the LED dice within direct line of sight, such as, for example by surrounding LED dice 222-226 with a suitable material designed to block direct light from the LED dice or mounting LED dice 222-226 within the substrate at a depth designed to block direct light from the LED dice. Modified internal sensors 228 can be implemented as any suitable sensor, such as, for example TK025PD also available from Tyntek of Taiwan, RoC,

Control of components within an LED light source assembly to achieve stable and reproducible color coordinates and light intensity is implemented utilizing a feedback control system including a digital signal processing (“DSP”) platform that is based on optical or a combination of thermal and optical feedback. In one embodiment, a conventional time control system periodically switches off one or more color groups of LED dice 222-226 for a predetermined period of time not observable to the human eye. In this example, thermal input may be utilized to enhance the control system. In another embodiment, a conventional frequency control system adds a different modulated frequency associated with each color group to the LED dice 222-226 output to aide in differentiation of different spectral groups within emitted light. In this embodiment, thermal input may be utilized to enhance the control system.

FIG. 3 is a side view of an embodiment of first stage optic 140 of light source assembly 100 illustrated in FIG. 1. In FIG. 3, first stage optic 300 includes reflective sidewall 310, submount area 320, encapsulated dielectric 330, an reflector 335, fins 340, 342, 344, refractive light paths 360, 361 and optional light tubes 350, 351. Although only two refractive light paths and optional light tubes are detailed for illustrative purposes, it should be understood that more may be utilized in implementation of the present invention. In an example and referring to FIGS. 2 and 4, the number of refractive light paths and optional light tubes utilized is equal to the number of external sensors mounted to the PCB. In this example, each refractive light path and associated optional light tube is co-located with an associated external sensor to provide refracted light to that external sensor.

In one embodiment, first stage optic 300 is implemented as a modified reflector cup package as described in Philips patent number 6,547,416 B2 titled “Faceted Multi-chip Package to Provide a Beam of Uniform White Light from Multiple Monochrome LEDs” issued Apr. 15, 2003. In an example and referring to FIGS. 1-3, first stage optic 300 is implemented as first stage optic 140 and PCB 210 and submount 220 are implemented as PCB 110 and submount 120 respectively. In this example (further detailed in FIG. 4), first stage optic 300 includes a base diameter of nine millimeters (9 mm) defining submount area 320, a height of sixty-six millimeters (66 mm), and an emission diameter of sixty millimeters (60 mm). The base diameter includes enough area to encompass submount 220 without encompassing external sensors 211-218 located on PCB 210. In another example, the base diameter does not fully encompass submount 220 but does include enough area to encompass the LED dice located on submount 220.

In one embodiment, first stage optic 300 includes facets 311-316 that enhance light emitted from first stage optic 300. In another embodiment and referring to first stage optic 140 of FIG. 1, first stage optic 300 is manufactured in other shapes, such as, for example a cone. First stage optic 300 may be manufactured from any suitable material, such as, for example aluminum (Al). In one embodiment, first stage optic 300 is manufactured as a single piece aluminum reflector cup including facets 311-316. In another embodiment, first stage optic 300 is manufactured as a two piece aluminum reflector cup including facets 311-316. In this embodiment, a first piece includes submount area 320 and encapsulated dielectric 330, and a second piece includes reflector 335. In this embodiment, the second piece including reflector 335 is an optional piece of first stage optic 300 and is included for additional focusing of emitted light. In yet another embodiment, first stage optic 300 is manufactured from a plastic material that is designed to mix/focus light output utilizing total internal reflection (TIR).

First stage optic 300 additionally includes a lining of reflective material to increase emitted light. In one embodiment, first stage optic 300 includes a lining of highly reflective aluminum (Al), such as, for example MIRO 27 extra bright rolled aluminum available from Alanod De of Ennepetal, Germany. In an example, highly reflective aluminum is cut into strips and positioned horizontally in the area between each of the facets 311-316.

First stage optic 300 further includes refractive light paths 360, 361 that are holes drilled into reflective sidewall 310 within encapsulated dielectric 330 of first stage optic 300 to provide a source of refracted light for external sensors. In one embodiment, light paths 360, 361 are holes one millimeter (1 mm) in diameter drilled into reflective sidewall 310. The light paths are aligned to provide refracted light to the external sensors. In one embodiment, refractive light paths 360, 361 are located between the base of first stage optic 300 and first facet 311. In an example and referring to FIGS. 2 and 3, each refractive light path 360, 361 is aligned with each external sensor 211-218 and provides a path for refracted light to travel from encapsulated dielectric 330 of first stage optic 300 to external sensors 211-218. In another example, optional light tubes 350, 351 are located within refractive light paths 360, 361 and provide a medium for refracted light to travel from encapsulated dielectric 330 of first stage optic 300 to external sensors 211-218. In this embodiment, light tubes 350, 351 provide an enhanced path for the refracted light to travel.

First stage optic 300 additionally includes fins 340, 342, 344 operatively coupled to first stage optics 300. Fins 340, 342, 344 provide a path for heat transfer from a printed circuit board to the ambient environment. Although only three fins are detailed for illustrative purposes, it should be understood that more may be utilized in implementation of the present invention. Fins 340, 342, 344 may be manufactured from any suitable thermally conductive material, such as, for example copper.

FIG. 4 is a three-dimensional view illustrating a LED light source assembly, in accordance with another embodiment of the present invention. LED light source assembly 400 includes PCB 410, submount 420, PCB heatsink 430, and first stage optics 440. LED light source assembly 400 additionally includes partition lines x₁, x₂, y₁, and y₂. Like named components function substantially similar to associated components in FIGS. 1-3, above. LED light source assembly 400 may include additional components not relevant to the present discussion.

PCB 410 is a mounting platform that is operatively coupled to submount 420, PCB heatsink 430, and first stage optics 440. PCB 410 includes circuitry necessary to allow submount 420 and components integrated within submount 420 to function as designed. In one embodiment, PCB 410 additionally includes interface input port 412 as well as additional mountings for discrete components 416-418 that are not integrated within submount 420, such as, for example unavoidable discrete components including inductors, capacitors and the like. Interface input port 412 provides a port for interface with submount 420 and hence assembly 400. In one embodiment, interface input port 412 provides a port for receiving operating instructions such as, for example color point instructions and on/off instructions. Interface input port 412 is designed to receive power and provide the received power to submount 420 via PCB 410 as well as providing a user interface with submount 420.

PCB 410 additionally includes external sensors 451-458 operatively coupled to PCB 410, such as, in a configuration as described in FIG. 2 above. The sensors may be implemented as any suitable sensor, for example photodetectors. The sensors provide input data for any control circuitry within LED light source assembly 400.

Additionally, PCB 410 provides a path for heat transfer from submount 420 to the ambient environment. In one embodiment, thermal build-up within submount 420 is transferred to PCB 410 due to physical contact between the two components. The thermal build-up within PCB 410 is then transferred to PCB heatsink 430 due to physical contact between the two components.

Submount 420 is a substrate including LED dice 425 and internal sensors 428. LED dice 425 and internal sensors 428 are operatively coupled to the substrate, such as, for example in a configuration as described in FIG. 2 above. In one embodiment, submount 420 further includes drive and control circuitry integrated within the substrate. In another embodiment, drive and control circuitry (e.g., drive MOSFETS) is located elsewhere within the assembly, such as, for example within an additional silicon chip operatively coupled to PCB 410 and in communication with submount 420. Submount 420 can be manufactured from any suitable material, such as, for example a silicon substrate.

LED dice 425 are direct emitting components that are surface mounted to submount 420. LED dice 425 are direct emitting optoelectronic devices that produce light when power is supplied causing them to forward bias. The light produced may be within the blue, green, red, amber or other portion of the spectrum, depending on the material utilized in manufacturing the LED dice.

PCB heatsink 430 functions to conduct and dissipate heat, as well as to provide support to PCB 410. PCB heatsink 430 is manufactured from a conductive material, such as, for example copper. In another embodiment, submount 420 is attached directly to PCB heatsink 430. In this embodiment, a portion of PCB 410 is removed allowing for submount 420 to be attached directly to PCB heatsink 430 allowing for a more efficient thermal transfer to occur.

First stage optics 440 is a reflector cup including a encapsulated dielectric 441 and an air portion 443. Encapsulated dielectric 441 includes a transparent dielectric having a refractive index greater than one (1), such as, for example silicone, plastic, or glass. In one embodiment, a combination silicone-plastic resin is utilized to form the encapsulated dielectric within encapsulated dielectric 441 of first stage optics 440. Air portion 443 functions as an externally mounted reflector. In one embodiment, air portion 443 is optional. In another embodiment, air portion 443 provides a reduction in width of a beam emitted from first stage optics 440, and hence LED light source assembly 400.

First stage optics 440 may additionally include fins 445 operatively coupled to first stage optics 440. Additionally, fins 445 are operatively coupled to PCB 410 and provide a path for heat transfer from PCB 410 to the ambient environment. In one embodiment, utilizing fins 445 allows transfer of thermal build-up within PCB 410 to fins 445 due to physical contact between the two components. Fins 445 may be manufactured from any suitable thermally conductive material, such as, for example copper.

In operation, LED light source assembly 400 receives power from interface input port 412. LED light source assembly 400 may receive user input from interface input port 412 as well. Power, in the form of direct current, is provided to submount 420 and to LED dice 425 surface mounted on submount 420 via PCB 410. The direct current causes LED dice 425 to forward bias and produce light. The light produced by LED dice 425 is mixed and is passed through encapsulated dielectric 441 of first stage optics 440. A majority portion of the mixed light passes through air portion 443 and is emitted from LED light source assembly 400. A portion of the mixed light is refracted at the dielectric/air interface and passes from encapsulated dielectric 441 to external sensors 451-458 via light paths 461-468. External sensors 451-458 receive the refracted mixed light and produce data for control circuitry based on the received mixed light. Additionally, internal sensors 428 receive direct light from one or more LED dice 425 and produce data for control circuitry based on the received direct light.

The control circuitry processes the received direct and mixed light and produces a control signal based on the received direct and mixed light. In one embodiment, the control circuitry produces a control signal that varies the amount of direct current provided to color groups of LED dice 425, based on the processed direct and mixed light. In another embodiment, the control circuitry produces a control signal that varies the amount of direct current provided to one or more specific LED dice 425, based on the processed direct and mixed light.

Partition lines x₁, x₂, y₁, and y₂ represent demarcations along PCB 410 where the printed circuit board is folded during the manufacturing process. In one embodiment, folding of a portion of PCB 410 along partition lines x₁, x₂, y₁, and y₂ and wrapping and attaching PCB 410 to first stage optics 440 allows LED light source assembly 400 to fit within a second stage optic, such as, for example a lighting bulb having a conventional appearance. In an example, portions of PCB 410 are folded along partition lines x₁, x₂, y₁, and y2 and wrapped and attached to first stage optics 440. In this example, portions of PCB 410 are removed allowing for fins 445 to be attached directly to first stage optics 440 through PCB 410 thereby allowing for a more efficient thermal transfer to occur.

The above-described apparatus and system for providing spectral output and intensity utilizing LEDs are example apparatus and implementations. These methods and implementations illustrate one possible approach for providing spectral output and intensity utilizing LEDs. The actual implementation may vary from the method discussed. Moreover, various other improvements and modifications to this invention may occur to those skilled in the art, and those improvements and modifications will fall within the scope of this invention as set forth in the claims below.

The present invention may be embodied in other specific forms without departing from its essential characteristics. The described embodiments are to be considered in all respects only as illustrative and not restrictive.

1. An integrated LED light system, the system comprising:
a printed circuit board (110, 410);
a submount (120, 420) mounted on said printed circuit board (110, 410);
an array of LEDs (125, 425) in electrical communication with said submount (120, 420) to receive at least one forward current, said array of LEDs (125, 425) including at least one LED (222-226, 425) for emitting at least one color of light in response to a reception of said at least one forward current from said submount (120, 420);
a heatsink (130, 430) supporting said circuit board (110, 410) to conduct and dissipate heat away from said printed circuit board (110, 410), said submount (120, 420), and said LEDs (125, 425); and
a reflector cup (140, 440) mounted on said printed circuit board (110, 410), said reflector cup (140, 440) in optical communication with said LEDs (125, 425) to focus said at least one color of light.

2. The system of claim 1, wherein said printed circuit board (110, 410) includes:
at least one partition (x₁, x₂, y₁, and y₂) to facilitate a folding of at least one portion of said printed circuit board (110, 410).

3. The system of claim 1, wherein said printed circuit board (110, 410) includes:
a hole sized to accommodate a mounting of said submount (120, 420) to said heatsink (130, 430).

4. The system of claim 1, wherein said at least one LED (125, 425) is a direct emitting optoelectronic device.

5. The system of claim 1, wherein said at least one LED (125, 425) is an unencapsulated die portion of an LED.

6. The system of claim 1, wherein said reflector cup (140, 440) includes:
a dielectric portion (330, 441) to enhance said at least one color of light emitted from said at least one LED (222-226, 425).; and
a reflector (335, 443) to focus said at least one color of light.

7. The system of claim 6, wherein said reflector cup (140, 440) further includes:
at least one light path (360, 361, 461, and 468) extending to said submount (120, 420) to optically communicate a refraction of the at least one color of light to said submount (120, 420).

8. The system of claim 7, wherein said reflector cup (140, 440) further includes:
at least one light tube (350, 351), each at least one light tube (350, 351) located within one of said at least one light path (360, 361, 461, 468).

9. The system of claim 7, further comprising:
at least one sensor (211-218, 451-458) mounted to said printed circuit board (110, 410), said sensor (211-218, 451-458) receiving the refracted light through said at least one light path (360, 361,461, and 468).

10. The system of claim 9, further comprising:
at least one sensor (228, 428) mounted to said submount (220, 420), each at least one sensor (228, 428) to receive a light emitted from one of said at least one LED.

11. The system of claim 1, further comprising:
at least one internal sensor (228, 428) mounted to said submount (220, 420), each at least one internal sensor (228, 428) to receive a color of light emitted from one of said at least one LED (222-226, 425).

12. The system of claim 1, further comprising:
at least one sensor (228, 428) mounted to said submount (220, 420) and surrounded by material to block direct light from said at least one LED (222-226, 425).

13. The system of claim 1, further comprising:
at least one internal sensor (228, 428) mounted within said submount (220, 420) at a depth to block direct light from said at least one LED (222-226, 425).

14. The system of claim 1, wherein said submount (120, 420) is a silicon substrate.

15. The system of claim 1, wherein said submount (120, 420) is an electrically-insulating, thermally conducting substrate selected from the group consisting of: aluminum nitride, silicon carbide, beryllium oxide, and diamond.

16. The system of claim 15, wherein said electrically-insulating, thermally conducting substrate further includes electrical connections deposited overlying said substrate to provide direct current to said LED (125, 425).
